(19) United States
(12) Patent Application Publication
(10) Pub. No.: US 2010/0308353 A1
(43) Pub. Date: Dec. 9, 2010

(54) DOUBLE SIDED ORGANIC LIGHT EMITTING DIODE (OLED)

(75) Inventors: Stefan Peter Grabowski, Neuss (DE); Claudia Michaela Goldmann, Kreuzau (DE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/867,898

(22) PCT Filed: Feb. 19, 2009
(86) PCT No.: PCT/IB09/50676

§ 371 Date: Aug. 17, 2010

(30) Foreign Application Priority Data
Feb. 22, 2008 (EP) 08101873.1

(51) Int. Cl. H01L 33/08

(52) U.S. Cl. 257/89; 257/E33.044

(57) ABSTRACT

The invention relates to a double sided light emitting diode device (1) comprising a transparent substrate layer (2) with a layer system, featuring at least a first emitting layer (3) and at least a second emitting layer (4).

### FIELD OF THE INVENTION

The present invention relates to a double sided light emitting diode device comprising a transparent substrate layer with a layer system featuring at least a first emitting layer and at least a second emitting layer.

### BACKGROUND OF THE INVENTION

Double sided light emitting diode devices are known form prior art as a light emitting device, which is suited to emit light in two different directions. When different emitting layers are stacked on each other, each layer can be operated separately or a number of single layers can be operated in a common way. Thus, different colors can be emitted both through said substrate layer and in the top side direction passing the topside of the device. Usually said substrate layer forms the bottom of said device, which is further on called the OLED. These bottom emitting or top emitting illumination devices basing on organic light emitting diodes are of great interest as superior flat-panel systems. These systems utilize current passing through a thin film of organic material to generate light. The color of light emitted and the efficiency of energy conversion from current to light are determined by the composition of the organic thin-film material. In addition, OLEDs comprise a substrate material as a carrier layer, which may be made of glass or different non-transmittive materials for top emitting OLEDs or which are made of transmittive materials for bottom emitting OLEDs. Furthermore, organic light emitting diodes consist of one or more very thin layers with a layer thickness of approximately 100 nm of organic substances on a glass substrate typically covered with an electrically conducting and optically transparent oxide for bottom emission or optically non-transparent material for the top emitting design of an OLED.

In the US patent application 2007/0126354 A1 is disclosed a double sided organic light emitting diode device with a first substrate and a second substrate disposed oppositely. A first organic light emitting diode device is disposed on a first substrate, whereas a second organic light emitting diode device is disposed on a second substrate to form two OLED-structures. A supporter disposed between the first OLED and the second OLED is provided to divide both OLEDs, in order to obtain a first emitting device on the first side and a second emitting device on the second side of the supporter. The supporter can be a metal alloy, a glass material, a quartz material or synthetic material. However, two substrate materials are necessary, as well as a separate encapsulation for each substrate. Thus, the deposition of the two OLEDs on different substrates leads to high costs in production of double sided organic light emitting diodes. Moreover the thickness of the entire device is enlarged, because at least two substrate layers are necessary, whereas the said supporter layer is arranged in a sandwich design. Thus, a double sided OLED comprising a layer system as described above features a low flexibility and is very expensive and complex in its arrangement.

The document WO 2005/043961 A2 discloses an organic light emitting diode with a single substrate layer comprising a layer succession with a first two-dimensional electrode made of a transparent material, two emitting layers made of a luminescent dielectric material, which are arranged on both sides of said first electrode. Said luminescent layers are transparent and are made of materials that can emit light with different wavelength. An electrode is assigned to each large surface of luminescent layers opposite the common electrode. A support layer, which forms a transparent substrate layer is located on one face side of the OLED. Unfortunately, each single layer is transparent. Thus, the OLED is only suited to emit either the color of the first emitting layer or the color of the second emitting layer, respectively a mixed color emission. The color, which is emitted by passing the bottom side and which is emitted by passing the top side is the same color at any time. Due to the transparency of the entire OLED device the emission of different colors may be not divided into a bottom side and a top side emission of the OLED device.

### SUMMARY OF THE INVENTION

Thus, the present invention has the objective to eliminate the above mentioned disadvantages. In particular it is an objective of the present invention to provide an OLED device, featuring an emission of a first color at the bottom side and an emission of a second color on the top side, whereas the OLED device features a simple layer design comprising a minimum number of different layers.

This objective is achieved by an organic light emitting diode device as taught by claim 1 of the present invention. A preferred embodiment of the invention is defined by the subclaims.

The invention discloses that the layer succession on said substrate layer features at least a bottom electrode layer, said first emitting layer, a non-transparent charge-generation layer, said second emitting layer and a transparent top electrode layer.

The layer system according to the present invention leads to the advantage that the OLED is performed as a non-transparent OLED. Only one single substrate layer is necessary, which has to be coated by a number of layers at the same side. The transparent substrate layer is coated with a bottom electrode layer, whereas the bottom electrode layer is coated with a first emitting layer. On top of said first emitting layer a non-transparent charge-generation layer is deposited. This layer is suited to divide said OLED into a first emitting side and into a second emitting side arranged opposite to the first emitting side. On top of said non-transparent charge-generation layer is deposited a second emitting layer, whereas the final layer is formed by a transparent top electrode layer. When both emitting layers are operated, e.g. said first emitting layer may emit orange light and said second emitting layer may emit green light. The emission of the orange light is enabled by passing said transparent substrate layer, whereas the emission of said green light is enabled by passing said transparent top electrode layer.

In its preferred embodiment said first emitting layer emits a first light spectrum passing said transparent substrate layer, whereas said second emitting layer emits in a second light spectrum passing said transparent top electrode layer. Thus, a bicolored organic light emitting diode device can be provided, whereas a first color is emitted at the first side and a second color is emitted on the opposite side. The emission of both spectrums is separated from each other without any interaction which may result in a color mix or interference effect.

Yet another embodiment of the present device can be seen in arranging a bottom electrode layer, which is performed as an anode layer featuring an Indium Tin Oxide (ITO) layer and said top electrode layer which is performed as a cathode layer featuring a Silver (Ag) layer. If a power supply is applied between the anode and the cathode the first emitting layer as well as said second emitting layer emit light. Thus, by using only one single power supply both OLED-systems may be operated. Said ITO-layer can be deposited as a thin film layer, which is transparent. The same transparency-effect can be achieved in the cathode layer, when the Silver-layer features a small thickness.

According to another preferred embodiment said nontransparent charge-generation layer features a n-doping at the interface to the first emitting layer and a p-doping at the interface to the second emitting layer. Thus, a p-n-transition is provided with a metal-layer in between the transition. Due to the application of the n-doping and the p-doping the efficiency of the OLED device can be increased.

As a preferred embodiment said non-transparent charge-generation layer is performed as an intermediate electrode layer comprising an Aluminum (Al) layer featuring a thickness of 30 nm to 200 nm, preferred 50 nm to 150 nm and most preferred 80 nm. In order to use the charge-generation layer as an intermediate electrode layer, the Aluminum-layer must be contacted by a wiring. Therefore a contacting pad has to be led through the layer system. With respect to the entire OLED device three wiring pads are necessary, whereas the first and the second wiring pad is contacted to the anode layer, performed by the ITO-layer and to the cathode layer, performed by the Silver-layer, whereas the third wiring is performed to the intermediate electrode layer.

Advantageously, said first emitting layer and said second emitting layer are operated by a power supply, whereas the power supply of said first emitting layer is separated from the power supply of the second emitting layer. The power supply of said first emitting layer is performed between said bottom electrode layer operating as an anode and said charge-generation layer operating as a cathode. Thus, by supplying a voltage between said electrodes the first emitting layer can emit light. The power supply of said second emitting layer is performed between said charge-generation layer operating as an anode and said top electrode layer operating as a cathode. By a voltage supply of said second emitting layer this layer may be operated independently from said first emitting layer.

Yet another embodiment of the present invention provides a top electrode layer, on which is performed a light outcoupling layer comprising a Zinc Selenide (ZnSe) layer or a Zinc Sulfide (ZnS) layer, whereas said layers feature a thickness of approximately 5 nm to 200 nm, preferred 15 nm to 80 nm and most preferred 30 nm or said light outcoupling layer comprises an organic layer like Alq3 or α-NPD featuring a thickness of 5 nm to 200 nm and preferred 20 nm to 80 nm. By applying a light outcoupling layer, the efficiency of light outcoupling can be increased.

The present invention is also embodied in a casing, whereas on said top electrode layer is performed a casing comprising a transparent glass cover or a thin film encapsulation. This encapsulation may comprise one or more double layers of silicon nitride (SiN) with a thickness of approximately 200 nm and silicon oxide (SiO₂) with a thickness of approximately 100 nm. The glass cover can be performed with a frame system, which may be glued onto the top surface of said OLED device, in order to protect the OLED device against moisture, contamination or mechanical damaging. According to yet another embodiment said glass cover may be glued directly onto the surface of the OLED. Furthermore, a combination of said thin film encapsulation, applied on the surface of the OLED, and said glass cover can be applied in common use to increase the durability and resistivity of the entire device.

In its preferred embodiment said device is used for decorative applications like self-illuminating lampshades. Said lampshade may perform the illuminant itself, whereas said lamp comprising an OLED-illuminant can be performed as a ceiling lamp, a wall light or any further kind of a lamp system. A multitude of lamp designs are available by applying said OLED-device featuring two emitting surfaces. As a preferred embodiment of a ceiling lamp said first emitting layer may emit a white colored light and is directed downwards into a room, e.g. above a dining table, a writing table etc. The second emitting layer may emit light in an upside direction, whereas this light may be a warm light for illuminating the room ceiling working as an indirect illumination.

Another preferred application of said double sided light emitting diode device may be designated for signage. Thus, said OLED device may be applied on glass door leaves comprising an entering color, emitted on the first side and an exit color, emitted on the second side of said device. Furthermore, said device may be applied as a road sign for traffic applications, e.g. comprising a white and a red emitting side.

In order to enlarge the functional range of said OLED device, on both sides of said charge-generation layer can be applied more than one emitting layer, in order to emit different colors of light at each side.

Additional details, characteristics and advantages of the objective of the invention are disclosed in the depending claims and the following description of the respective figures—which are shown in an exemplary fashion—showing preferred embodiments of the invention, which will be described in conjunction with an accompanying figure, in which:

### BRIEF DESCRIPTION OF THE DRAWINGS

FIG. 1: shows a schematic view of the layer system according to the present invention.

### DETAILED DESCRIPTION OF EMBODIMENTS

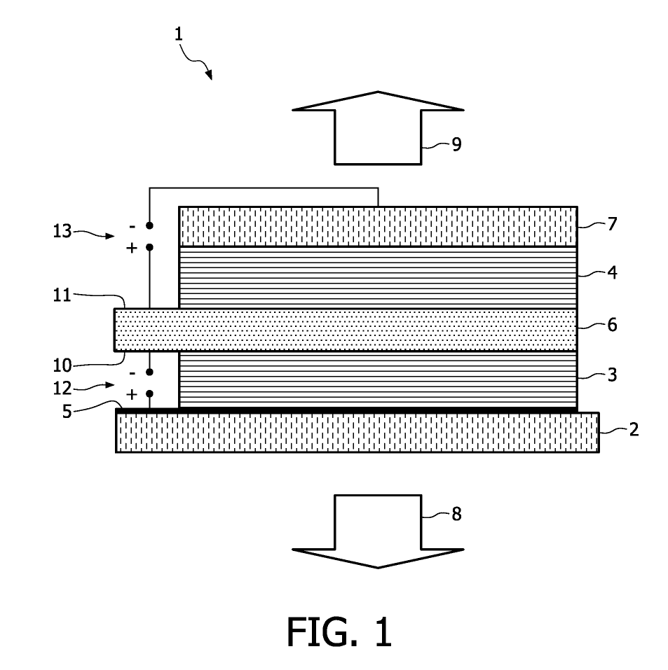

The embodiment described in FIG. 1 comprises a layer succession to provide a double sided light emitting diode device 1. A substrate layer 2 performs a carrier, on which the layer succession is deposited on only one side. The layer succession comprises at least a bottom electrode layer 5, followed by a first organic stack, i.e., one or more layers of organic material, which comprise a first emitting layer 3, followed by a non-transparent charge-generation layer 6, followed by a second organic stack, i.e., one or more layers of organic material, which comprise a second emitting layer 4, whereas the final layer is performed by a transparent top electrode layer 7. This layer succession features only a basic construction. In between said layers may be deposited further layers in order to increase the efficiency or to increase the durability by applying a protection layer like a glass cover or a thin film layer working as a cover layer. The power supply of said first emitting layer 3 and said second emitting layer 4 can be provided by independent power supply arrangements. Thus, said first emitting layer 3 can be supplied by a first power supply 12 and said second emitting layer 4 may be supplied by a second power supply 13. To increase the efficiency of said OLED device 1 said charge-generation layer 6 can be provided with dopings on the interfaces to the first and the second emitting layer 3 and 4. Thus, said non-transparent charge-generation layer 6 features a n-doping 10 at the interface to said first emitting layer 3 and a p-doping 11 at the interface to said second emitting layer 4. The non-transparent charge-generation layer 6 can be performed as an intermediate electrode layer comprising an Aluminum (Al) layer featuring a thickness of approximately 80 nm. Thus, the layer 6 is non-transparent in order to provide an optical in separation between the first emitting layer 3 and the second emitting layer 4. Thus, said first emitting layer 3 may emit light by passing said transparent substrate layer 2 with a first light spectrum 8, whereas said second emitting layer 4 may emit light by passing said top electrode layer 7 with a second light spectrum 9.

According to an advanced dual-OLED device 1 the following layer system can be applied on said substrate layer 2. The layer succession comprises at least a ITO-layer 5, followed by a p-doping layer 11, comprising a hole injection layer MTDATA:F₄-TCNQ (1%) with a thickness of 40 nm. The next layer is a hole conducting layer α-NPD 10 nm. This layer is followed by said first emitting layer 3, comprising a α-NPD:Ir(MDQ)₂(acac) (10%) with a thickness of 20 nm. The next layer is an electrode transport layer (BA1q) with a thickness of 20 nm. After this layer an n-doping layer is performed as a LiF-layer with a thickness of 1 nm. This layer is followed by said charge-generation layer 6, performed as an Aluminum layer with a thickness of 80 nm. This layer is followed by a p-doping hole injection layer, comprising MTDATA:F₄-TCNQ (8%) with a thickness of 40 nm. The next layer is a hole conductive layer α-NPD with a thickness of 10 nm. The next layer is said second emitting layer 4, comprising TCTA:Ir(ppy)₃ (8%) with a thickness of 25 nm. The next layer is an electron conductive layer, comprising BA1q with a thickness of 55 nm. The next layer is an n-doping layer comprising LiF with a thickness of 1 nm, whereas this layer is covered by a thin Al-layer comprising a thickness of 1.5 nm. The next layer is a transparent Silver-layer with a thickness of 15 nm, followed by a light outcoupling layer, comprising ZnSe with a thickness of 30 nm.

The present invention is not limited by the embodiment described above, which is represented as an example only and can be modified in various ways within the scope of protection defined by the depending patent claims. Thus, the invention is also applicable to different embodiments, in particular with several emitting layers 3 and 4 on both sides of said charge-generation layer 6. Thus, said OLED 1 is suited to emit different colors on both sides of said device.

### LIST OF NUMERALS

1 Light Emitting Diode Device (OLED)
2 transparent substrate
3 first emitting layer
4 second emitting layer
5 bottom electrode layer
6 charge-generation layer
7 top electrode layer
8 first light spectrum
9 second light spectrum
10 n-doping
11 p-doping
12 first power supply
13 second power supply

1. A double sided light emitting diode device comprising a transparent substrate layer with a layer system, featuring at least a first emitting layer and at least a second emitting layer, wherein the layer succession on said substrate layer comprises a bottom electrode layer, said first emitting layer, a non-transparent charge-generation layer, said second emitting layer and a transparent top electrode layer and wherein said non-transparent charge-generation layer comprises a n-doping at the interface to the first emitting layer and a p-doping at the interface to the second emitting layer.

2. A double sided light emitting diode device according to claim 1, wherein said first emitting layer emits light in a first light spectrum (8) by passing said transparent substrate layer, wherein said second emitting layer emits light in a second light spectrum by passing said transparent top electrode layer.

3. A double sided light emitting diode device according to claim 1 wherein said bottom electrode layer is an anode layer comprising Indium Tin Oxide (ITO) and said top electrode layer is a cathode layer comprising silver.

4. A double sided light emitting diode device according to claim 1 wherein said non transparent charge-generation layer comprises a n-doping at the interface to the first emitting layer and a p-doping (11) at the interface to the second emitting layer.

5. A double sided light emitting diode device according to claim 1, wherein said non transparent charge-generation layer is an intermediate electrode layer comprising aluminum and having a thickness of 30 nm to 200 nm.

6. A double sided light emitting diode device according to claim 1, wherein the first emitting layer and the second emitting layer are operated by a power supply, wherein the power supply (12) of said first emitting layer is separated from the power supply (13) of said second emitting layer.

7. A double sided light emitting diode device according to claim 6, wherein the power supply (12) of said first emitting layer is performed between said bottom electrode layer operating as an anode and said charge-generation layer operating as a cathode, wherein the power supply (13) of said second emitting layer is performed between said charge-generation layer operating as an anode and said top electrode layer operating as a cathode.

8-11. (canceled)

12. A double sided light emitting diode device according to claim 1, wherein a light outcoupling layer comprising zinc selenide or zinc sulfide and having a thickness of approximately 15 nm to 80 nm is disposed over said top electrode layer.

13. A double sided light emitting diode device according to claim 1, wherein a light outcoupling organic layer comprising Alq₃ or α-NPD and having a thickness of approximately 20 nm to 80 nm is disposed over said top electrode layer.

14. A double sided light emitting diode device according to claim 5, wherein said non-transparent charge-generation layer is an intermediate electrode layer comprising aluminum and having a thickness of about 80 nm.

15. A double sided light emitting diode device according to claim 1, wherein a casing comprising a transparent glass cover or a thin film encapsulation comprising one or more double layers of silicon nitride (SiN) with a thickness of approximately 200 nm and silicon oxide (SiO₂) with a thickness of approximately 100 nm is disposed over said top electrode layer.
